(19) United States
(12) Patent Application Publication
(10) Pub. No.: US 2026/0040834 A1
(43) Pub. Date: Feb. 5, 2026

(54) SEMICONDUCTOR QUANTUM DOT

(71) Applicant: Advanced Micro Devices, Inc., Santa Clara, CA (US)

(72) Inventor: Russell C. McMullan, Austin, TX (US)

(73) Assignee: Advanced Micro Devices, Inc., Santa Clara, CA (US)

(21) Appl. No.: 18/677,570

(22) Filed: May 29, 2024

(51) Int. Cl. H10N 60/10; B82Y 10/00; G06N 10/40; H10N 60/01

(52) U.S. Cl. CPC H10N 60/128; H10N 60/01; H10N 60/11; B82Y 10/00; G06N 10/40

(57) ABSTRACT

The disclosed device includes a quantum dot structured formed with a semiconductor channel on a substrate and between two barrier gates. A plunger gate is disposed on top of the quantum dot structure and electrodes are on sidewalls of the quantum dot structure next to the plunger gate. Applying voltages to the electrodes can control electron positioning in the quantum dot structure. Various other methods, systems, and computer-readable media are also disclosed.

### BACKGROUND

Classical computers perform calculations with information encoded as binary digits (“bits”), which represent one of two discrete states (e.g., “0” or “1). Bits are often implemented with transistors having different voltage values representing the discrete states. Quantum computers can perform calculations using quantum algorithms in which information is encoded as quantum bits (“qubits”). In contrast to classical bits, qubits can represent both states (e.g., “0” and “1”) in a quantum mechanical phenomenon referred to as superposition.

Further, in contrast to transistors generally representing a single state, qubits are implemented with hardware that represent the qubit with a particle (e.g., electrons, photons, etc.) that can represent superposition (e.g., via an energy state, spin, etc.), such as electrons in a semiconductor quantum dot. A semiconductor quantum dot can correspond to a qubit implemented with a semiconductor structure that isolates/traps electrons. However, decoherence can happen when a quantum system interacts with its surrounding environment, which deteriorates the superposition of the particle, and introduces error and/or noise to the quantum state and/or encoded data. For example, the electron in the semiconductor quantum dot can experience decoherence due in part to the physical characteristics of the semiconductor quantum dot itself.

### BRIEF DESCRIPTION OF THE DRAWINGS

The accompanying drawings illustrate a number of exemplary implementations and are a part of the specification. Together with the following description, these drawings demonstrate and explain various principles of the present disclosure.

FIG. 1 is a block diagram of an exemplary quantum computing system.

FIG. 2 is a block diagram of an exemplary classical computing system for interfacing with a quantum computing system.

FIGS. 3A-C are diagrams of exemplary semiconductor quantum dot devices based on semiconductor electron qubit traps.

FIGS. 4A-D are a diagrams of additional semiconductor quantum dot devices.

FIG. 5 is a flow diagram of an exemplary method for reducing quantum bit errors by controlling electron positioning in a semiconductor quantum dot.

FIG. 6 is a flow diagram of an exemplary method of fabricating a semiconductor quantum dot device described herein.

Throughout the drawings, identical reference characters and descriptions indicate similar, but not necessarily identical, elements. While the exemplary implementations described herein are susceptible to various modifications and alternative forms, specific implementations have been shown by way of example in the drawings and will be described in detail herein. However, the exemplary implementations described herein are not intended to be limited to the particular forms disclosed. Rather, the present disclosure covers all modifications, equivalents, and alternatives falling within the scope of the appended claims.

### DETAILED DESCRIPTION

The present disclosure is generally directed to a semiconductor electron trap that can improve reliability and extend coherence by controlling positions of electrons for the semiconductor quantum dot. As will be explained in greater detail below, implementations of the present disclosure include a qubit implemented with an electron trap structure of a semiconductor channel that is defined between first and second barrier gates and can trap electrons. A plunger gate electric node on the electron trap can control a potential well, a key component of the quantum dot in which electrons can reside. The spin or charge state of the electrons can be programmed using direct voltage, direct current (DC), and/or alternating current (AC), such as electron spin resonance (ESR) through magnetic fields, AC through conductor coils, etc. The systems and methods described herein provide two additional nodes around the quantum dot to improve the programming, fidelity, stability, and coherence of the quantum dot. The two additional nodes are adjacent to the plunger gate along sidewalls of the electron trap and further control positions of the electrons. Applying appropriate voltage signals using one or more of the plunger gate, bottom bulk electrode, first electrode, and/or second electrode can position the electrons away from irregular material structures typically at silicon to oxide interface regions as one example. These irregular material structures can cause charge or spin state loss and decoherence such that keeping the electrons in homogeneous material regions within a potential well of the electron trap is desired. Moreover, the DC and/or AC signals on the additional nodes can provide electric field isolation around the electrons in a manner to increase tolerance to noise, spurious electric fields, etc. The control signals and/or voltage signals described herein can in some implementations relate to several possible purposes such as potential well formation, electron spatial location, electron energy/spin state, and noise isolation.

In one implementation, a device for an improved semiconductor quantum dot includes device comprising a semiconductor channel, a first barrier gate surrounding the semiconductor channel, a second barrier gate surrounding the semiconductor channel, an electron trap of the semiconductor channel defined between the first and second barrier gates to trap an electron corresponding to a qubit, a plunger gate over the electron trap and configured for a control signal for the qubit, a first electrode near the electron trap and configured for a first voltage signal, and a second electrode near the electron trap and configured for a second voltage signal, and a bottom electrode opposite the plunger gate.

In some examples, the electron trap comprises an oxide interface region and the first and second electrodes are configured to position the electron away from the oxide interface region. In some examples, the bottom electrode is bulk silicon and is configured to position the electron away from the oxide interface region. In some examples, the plunger gate is further configured to position the electron away from the oxide interface region.

In some examples, at least one of the first and second voltage signals corresponds to a direct current (DC) signal or a fluctuating voltage signal. In some examples, device further includes a second electron trap of the semiconductor channel to trap a second electron corresponding to a second qubit. In some examples, the second qubit is configured for entanglement with the first qubit.

In some examples, device further includes a third barrier gate surrounding the semiconductor channel, wherein the second electron trap is defined between the second and third barrier gates. In some examples, the device further includes a second plunger gate over the second electron trap and configured for a second control signal for the second qubit, and a second bottom electrode oppose the second plunger gate. In some examples, the device further includes a third electrode near the second electron trap and configured for a third voltage signal, and a fourth electrode near the second electron trap opposite the third electrode and configured for a fourth voltage signal.

In some examples, the second electron trap comprises a second oxide interface region and the third and fourth electrodes are configured to position the second electron away from the second oxide interface region. In some examples, at least one of the third and fourth voltage signals corresponds to a direct current (DC) signal or a fluctuating voltage signal.

In one implementation, a system for an improved quantum dot includes a control system, and a quantum processing device comprising a semiconductor channel, a first barrier gate surrounding the semiconductor channel, a second barrier gate surrounding the semiconductor channel, an electron trap of the semiconductor channel defined between the first and second barrier gates to trap an electron corresponding to a qubit, the electron trap comprising an oxide interface region, a plunger gate over the electron trap and configured for a control signal for the qubit, a first electrode adjacent the plunger gate on a first side of the electron trap and configured for a first voltage signal, a second electrode adjacent the plunger gate on a second side of the electron trap opposite the first side and configured for a second voltage signal, and a bottom electrode opposite the plunger gate. In some examples, the control system is configured to coordinate the control signal, the first voltage signal, and the second voltage signal to position the electron away from the oxide interface region.

In some examples, at least one of the first and second voltage signals corresponds to a direct current (DC) signal or a fluctuating voltage signal. In some examples, the quantum processing device further comprises a third barrier gate surrounding the semiconductor channel, a second electron trap of the semiconductor channel defined between the second and third barrier gates to trap a second electron corresponding to a second qubit, and a second plunger gate over the second electron trap and configured for a second control signal for the second qubit.

In some examples, the second qubit is configured for entanglement with the first qubit. In some examples further includes a third electrode adjacent the second plunger gate on a first side of the second electron trap and configured for a third voltage signal, and a fourth electrode adjacent the second plunger gate on a second side of the second electron trap opposite the first side and configured for a fourth voltage signal. In some examples, the second electron trap comprises a second oxide interface region and the control system is configured to coordinate the second control signal, the third voltage signal, and the fourth voltage signal to position the second electron away from the second oxide interface region. In some examples, at least one of the third and fourth voltage signals corresponds to a direct current (DC) signal or a fluctuating voltage signal.

In one implementation, a method for manufacturing an improved semiconductor quantum dot includes (i) forming a semiconductor channel on a substrate, (ii) forming a plurality of barrier gate structures over the semiconductor channel, (iii) forming a plunger gate node structure over the semiconductor channel between a pair of the plurality of barrier gate structures to form a semiconductor quantum dot, (iv) forming a pair of opposing electrodes near the semiconductor quantum dot.

In some examples, method further includes forming a second plunger gate node structure over the semiconductor channel between a second pair of the plurality of barrier gate structures to form a second semiconductor quantum dot, and forming a second pair of opposing electrodes near the second semiconductor quantum dot.

In one implementation, a method for controlling electron positioning for a semiconductor quantum dot includes (i) programming a qubit implemented with a electron trap of a semiconductor channel having a plunger gate over the electron trap for applying a control signal, (ii) applying a first voltage signal using a first electrode adjacent the plunger gate on a first side of the electron trap, (iii) applying a second voltage signal using a second electrode adjacent the plunger gate on a second side of the electron trap opposite the first side, (iv) applying control signal to the bulk electrode and (v) controlling positions and isolation of electrons in the electron trap using the control signals, the plunger, the bulk, the first voltage signal, and the second voltage signal.

In some examples, the method further includes (vi) programming a second qubit implemented with a second electron trap of the semiconductor channel having a second plunger gate over the second electron trap for applying a second control signal, (vii) applying a third voltage signal using a third electrode adjacent the second plunger gate on a third side of the second electron trap, (viii) applying a fourth voltage signal using a fourth electrode adjacent the second plunger gate on a fourth side of the second electron trap opposite the third side, and (ix) controlling positions of a second electron in the second electron trap using the second control signal, the third voltage signal, and the fourth voltage signal.

In one implementation, the additional electrodes are located in adjacent structures not part of the plunger gate. Furthermore, the adjacent electrical nodes may be above or below the plunger gate. The purpose of the additional nodes being electron spatial control and noise suppression which assists with electron charge/spin state control nodes of current art.

Features from any of the implementations described herein can be used in combination with one another in accordance with the general principles described herein. These and other implementations, features, and advantages will be more fully understood upon reading the following detailed description in conjunction with the accompanying drawings and claims.

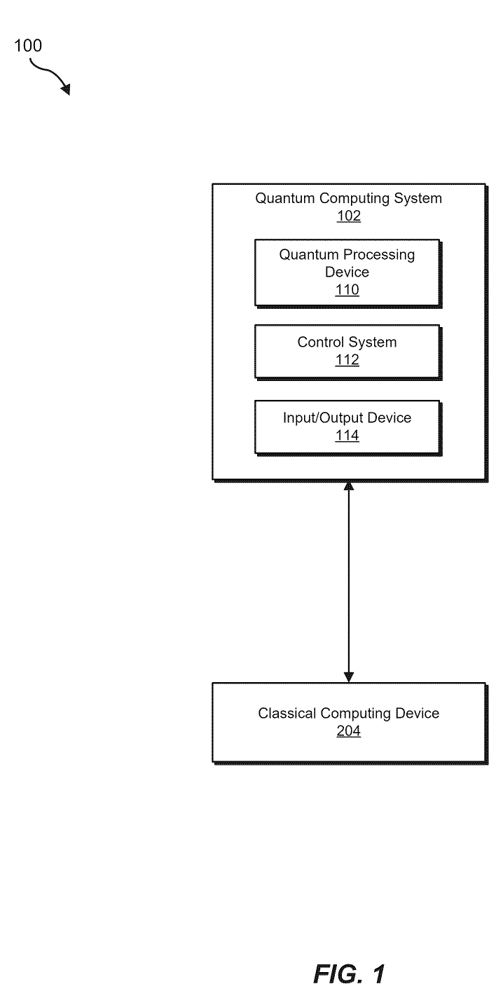

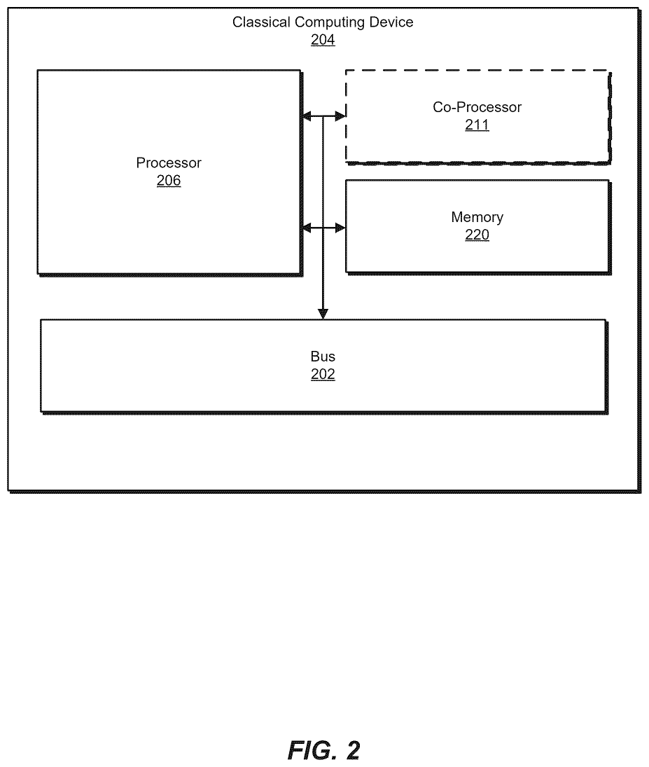

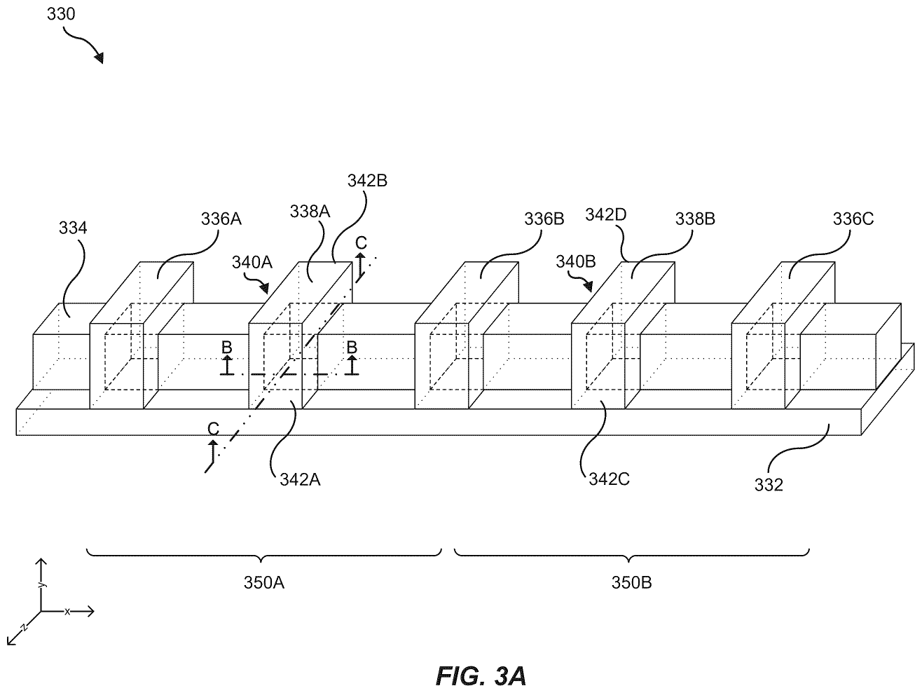

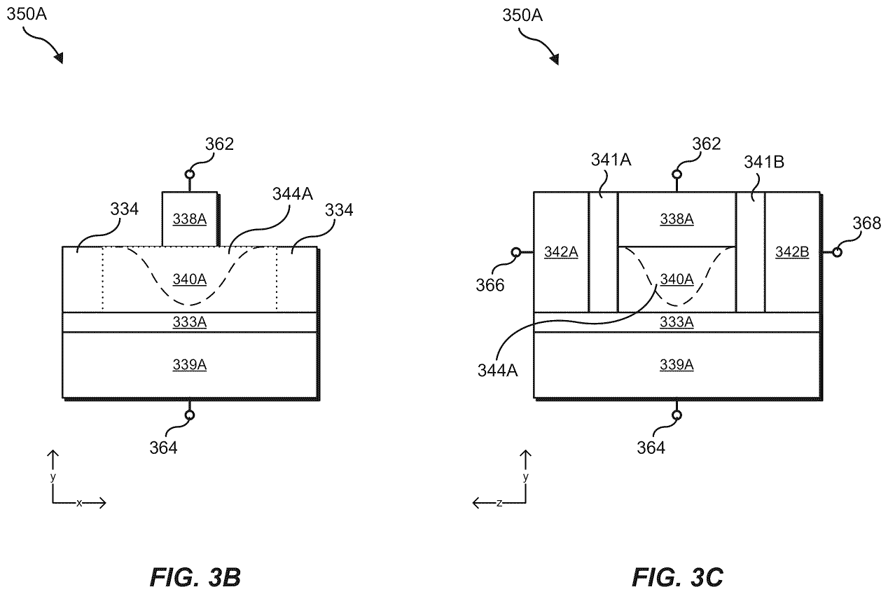

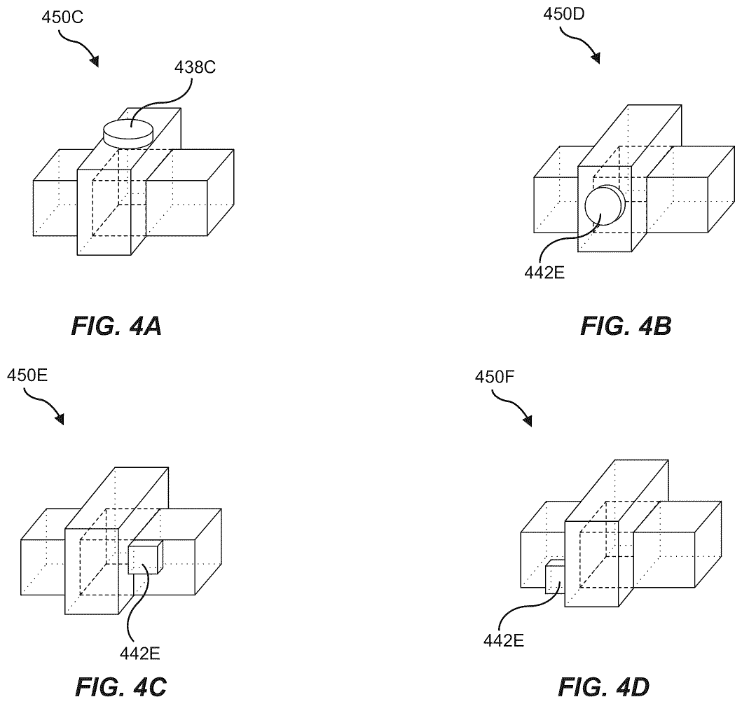

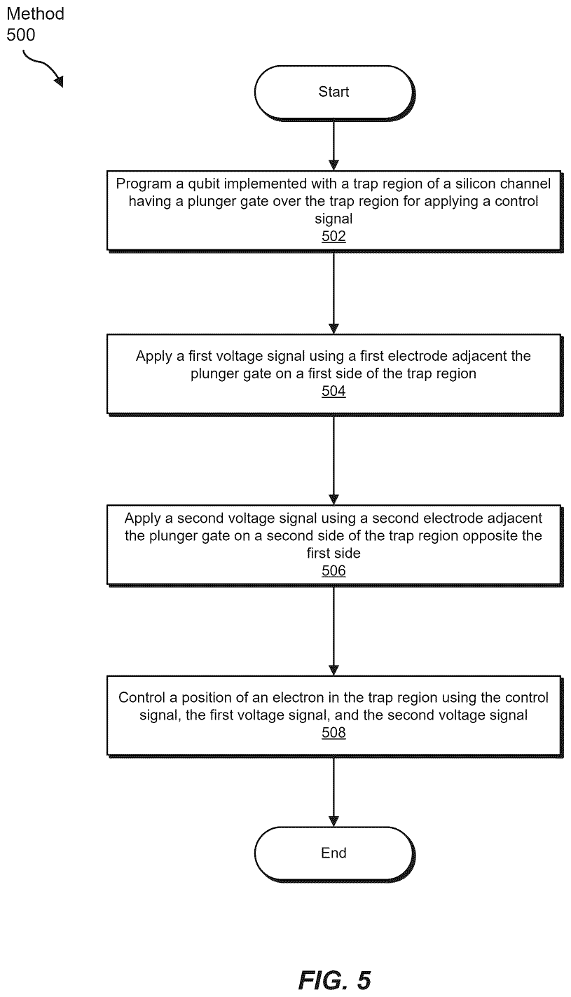

The following will provide, with reference to FIGS. 1-5, detailed descriptions of semiconductor electron qubit traps and controlling electron positioning. Detailed descriptions of example systems usable for quantum computing will be provided in connection with FIGS. 1 and 2. Detailed descriptions of example semiconductor electron traps will be provided in connection with FIGS. 3A-3C and 4A-4B. Detailed descriptions of corresponding methods will also be provided in connection with FIG. 5.

FIG. 1 illustrates an example quantum computing environment 100 including a quantum computing system 102 and in some implementations, a classical computing device 204. Quantum computing system 102 can refer to any device capable of performing quantum calculations and/or quantum algorithms using data/information encoded in qubits and through manipulations of the qubits. Quantum computing system 102 includes a quantum processing device 110, a control system 112, and an input/output device 114. Quantum processing device 110 corresponds to a device capable of implementing one or more qubits (e.g., each qubit being a particle that maintains a quantum state) akin to a quantum memory, as well as perform operations on the qubits, akin to a quantum processor.

Control system 112 corresponds to hardware and/or software that can interface with or otherwise interact with quantum processing device 110 for executing quantum programs, quantum algorithms, and/or other quantum computing tasks. For example, control system 112 can apply control signals to program, manipulate (e.g., change states), and/or read/measure quantum states of the qubits of quantum processing device 110, for instance to apply one or more quantum circuits. A quantum circuit can correspond to a model for quantum computation that can include quantum gates (e.g., analogous to logic gates of a classical computer), measurements (e.g., measuring a qubit which can involve interaction with a quantum measurement device that collapses a superposition of the qubit into a classical state to observe a property such as position, momentum, spin, energy, etc. and extract information), initializing qubits, etc. In some implementations, control system 112 can interface with or otherwise be integrated with a classical computing system (e.g., classical computing device 204) for implementing quantum circuits (e.g., also referred to as quantum instructions) which in some examples can be written in a quantum programming language.

Input/output device 114 can correspond to any interface device for inputting data into quantum computing system 102 and/or outputting data from quantum computing system 102. For instance, control system 112 can receive quantum instructions (e.g., from classical computing device 204) via input/output device 114, perform the quantum instructions using quantum processing device 110, and output a result of the quantum instructions through input/output device 114, such as to classical computing device 204 for further processing/display.

In some implementations, quantum computing environment 100 can be a hybrid computing architecture having components of both quantum computers (e.g., quantum computing system 102) and classical computers (e.g., classical computing device 204). FIG. 2 is a block diagram of an example classical computing device 204 that in some implementations can interface with, be integrated with, and/or otherwise operate with a quantum computing system, as described herein. Classical computing device 204 can correspond to a standalone computing device, such as a desktop computer, a laptop computer, a server, a tablet device, a mobile device, a smartphone, a wearable device, an augmented reality device, a virtual reality device, a network device, and/or an electronic device that can be integrated with another device. As illustrated in FIG. 2, classical computing device 204 includes one or more memory devices, such as memory 220. Memory 220 generally represents any type or form of volatile or non-volatile storage device or medium capable of storing data and/or computer-readable instructions. Examples of memory 220 include, without limitation, Random Access Memory (RAM), Read Only Memory (ROM), flash memory, Hard Disk Drives (HDDs), Solid-State Drives (SSDs), optical disk drives, caches, variations, or combinations of one or more of the same, and/or any other suitable storage memory.

As illustrated in FIG. 2, example classical computing device 204 includes one or more physical processors, such as processor 206, which can correspond to one or more processors (e.g., a host processor along with a co-processor, which in some examples can be separate processors). Processor 206 generally represents any type or form of hardware-implemented processing unit capable of interpreting and/or executing computer-readable instructions. In some examples, processor 206 accesses and/or modifies data and/or instructions stored in memory 220. Examples of processor 206 include, without limitation, one or more instances of chiplets (e.g., smaller and in some examples more specialized processing units that can coordinate as a single chip), microprocessors, microcontrollers, Central Processing Units (CPUs), Field-Programmable Gate Arrays (FPGAs) that implement softcore processors, Application-Specific Integrated Circuits (ASICs), systems on chip (SoCs), digital signal processors (DSPs), Neural Network Engines (NNEs), accelerators, accelerated processing units (APUs), portions of one or more of the same, variations or combinations of one or more of the same (e.g., a host processor and a co-processor), and/or any other suitable physical processor(s). Further, in some examples, processor 206 can be a general-purpose processor that can be capable, without significant limitation, of various computing tasks, as opposed to a special purpose processor that can be limited in computing tasks (e.g., specially designed for particular computing tasks such as moving data, performing certain mathematical operations, etc.), although in other examples processor 206 can correspond to and/or incorporate one or more special purpose processors.

As also illustrated in FIG. 2, example classical computing device 204 can in some implementations optionally include one or more physical co-processors, such as co-processor 211, which in other implementations can be integrated with or otherwise represented by processor 206. Co-processor 211 generally represents any type or form of hardware-implemented processing unit capable of interpreting and/or executing computer-readable instructions, which in some examples works in conjunction and/or based on instructions from a host/main processor such as a CPU (e.g., processor 206). In some examples, co-processor 211 accesses and/or modifies data and/or instructions stored in memory 220. Examples of co-processor 211 include, without limitation, chiplets (e.g., smaller and in some examples more specialized processing units that can coordinate as a single chip), microprocessors, microcontrollers, graphics processing units (GPUs), Field-Programmable Gate Arrays (FPGAs) that implement softcore processors, Application-Specific Integrated Circuits (ASICs), systems on chip (SoCs), digital signal processors (DSPs), Neural Network Engines (NNEs), accelerators, accelerated processing units (APUs), portions of one or more of the same, variations or combinations of one or more of the same, and/or any other suitable physical processor. Further, in some implementations, co-processor 211 can correspond to a quantum processing device, such as quantum processing device 110.

FIG. 2 also includes a bus 202 that can correspond to any bus, circuitry, connections, and/or any other communicative pathways for sending communicative signals, based on one or more communication protocols, between components/devices (e.g., processor 206, memory 220, and/or co-processor 211, etc.). In some implementations, bus 202 can further connect, via wireless and/or wired connections, to other devices, such as peripheral devices external to or partially integrated with classical computing device 204. Although not illustrated in FIG. 2, classical computing device 204 can be coupled to a display device (e.g., via bus 202).

FIG. 3A illustrates an isometric view of a simplified example semiconductor qubit device 330, which can correspond to quantum processing device 110 and/or a portion thereof. As illustrated in FIG. 3, semiconductor qubit device 330 includes a substrate 332, a semiconductor channel 334, a barrier gate 336A (e.g., a left barrier gate), a barrier gate 336B (e.g., a center barrier gate), a barrier gate 336C (e.g., a right barrier gate), a plunger gate 338A (e.g., a left plunger gate), a plunger gate 338B (e.g., a right plunger gate), an electron trap 340A, an electron trap 340B, an electrode 342A (e.g., a front electrode), an electrode 342B (e.g., a back electrode), an electrode 342C (e.g., a front electrode), and an electrode 342D (e.g., a back electrode). Substrate 332 can correspond to any appropriate substrate material for supporting the structures as illustrated. In some implementations, substrate 332 can be used for fabricating structures and subsequently removed and/or further modified. The gate structures (e.g., barrier gate 336A, barrier gate 336B, barrier gate 336C, plunger gate 338A, and/or plunger gate 338B) can comprise appropriate conductive/metallic material, and the electrode structures (e.g., electrode 342A, electrode 342B, electrode 342C, and/or electrode 342D) can comprise appropriate conductive/metallic material. In addition, although not explicitly illustrated in FIG. 3A, additional structures, layers, and/or materials can further support the illustrated structures, such as an insulating/dielectric material (e.g., an oxide) between different materials/structures (e.g., an oxide region between semiconductor channel 334 and gate material).

Semiconductor qubit device 330 can correspond to two semiconductor quantum dot qubits, such as semiconductor quantum dot 350A and semiconductor quantum dot 350B (each corresponding to a qubit). A quantum dot can refer to a device having semiconductor nanocrystals in which electrons in the nanocrystal can be excited to states of higher energy as well as release its energy (e.g., as light) or change spin/orbit characteristics as spin up/down. The semiconductor materials/structures referred to herein can correspond to any appropriate semiconductor material (e.g., Group IV semiconductors such as silicon or germanium that can be isotopically purified to enable long quantum coherence).

The first quantum dot (e.g., semiconductor quantum dot 350A) can correspond to a left half of semiconductor qubit device 330 in FIG. 3A. Barrier gate 336A and barrier gate 336B can surround semiconductor channel 334 over substrate 332 (e.g., surrounding the three sides, front, top, and back, of semiconductor channel 334 not touching substrate 332) as shown. By applying appropriate voltages to barrier gate 336A and barrier gate 336B, electrons can be trapped in electron trap 340A (e.g., a region of semiconductor channel 334 defined between barrier gate 336A and barrier gate 336B). Plunger gate 338A is disposed on top of electron trap 340A and application of control signals can initialize, manipulate, and/or measure quantum states of the electron in electron trap 340A. In some implementations, the control signal can also assist in forming the potential well, described further below. Electrode 342A can be disposed on a front side of electron trap 340A and electrode 342B can be disposed on a back side (opposite the front side) of electron trap 340A. However, in other examples, electrode 342A and/or electrode 342B can be positioned in other locations, such as in other structures separate from plunger gate 338A, as well as above or below plunger gate 338A. Further, in other examples, additional electrodes can be used. As will be described further below, voltage signals can be applied to electrode 342A and/or electrode 342B for electron spatial control and noise suppression that can assist with electron charge/spin state control nodes (e.g., plunger gate 338A and/or a bottom/bulk electrode).

The second quantum dot (e.g., semiconductor quantum dot 350B) can correspond to a right half of semiconductor qubit device 330 in FIG. 3A. Barrier gate 336B and barrier gate 336C can surround semiconductor channel 334 over substrate 332 (e.g., surrounding the three sides, front, top, and back, of semiconductor channel 334 not touching substrate 332) as shown. By applying appropriate voltages to barrier gate 336B and barrier gate 336C, electrons can be trapped in electron trap 340B (e.g., a region of semiconductor channel 334 defined between barrier gate 336B and barrier gate 336C). Plunger gate 338B is disposed on top of electron trap 340B and application of control signals can initialize, manipulate, and/or measure quantum states of the electron in electron trap 340B. In some implementations, the control signal can also assist in forming the potential well, described further below. Electrode 342C can be disposed on a front side of electron trap 340B and electrode 342D can be disposed on a back side (opposite the front side) of electron trap 340B. However, in other examples, electrode 342C and/or electrode 342D can be positioned in other locations, such as in other structures separate from plunger gate 338B, as well as above or below plunger gate 338B. Further, in other examples, additional electrodes can be used. As will be described further below, voltage signals can be applied to electrode 342C and/or electrode 342D.

Quantum computing can also utilize another quantum mechanics phenomenon referred to as quantum entanglement. When particles are entangled, a state of one of the particles can be intrinsically connected to a state of the other particles regardless of distance between the particles such that the states of the entangled particles are instantaneously influenced (e.g., when one particle is measured). In some implementations, the two quantum dots described herein can correspond to entangled qubits.

Referring to semiconductor quantum dot 350A, FIG. 3B provides a representational cross-sectional view along the B-B axis (shown in FIG. 3A), and FIG. 3C provides a representational cross-sectional view along the C-C axis (shown in FIG. 3B), which are not necessarily drawn to scale and include different features for explanatory reasons.

Turning to FIG. 3B, FIG. 3B illustrates electron trap 340A formed from semiconductor channel 334. Although not explicitly shown in FIG. 3B, applying an appropriate voltage to barrier gate 336A (e.g., which would be on the left of FIG. 3B) and to barrier gate 336B (e.g., which would be on the right side of FIG. 3B) along with appropriate source and drain voltages, can keep electrons in electron trap 340A. Although the description herein refers to electrons, this can also refer to any other particle and/or any other number of particles (e.g., one or more electrons, electron holes, etc., in any combination) which can behave similar to a single particle/electron.

In some examples, electron traps 340A can include a potential well region 344A (delineated by a dashed line in FIGS. 3B and 3C) which can correspond to electron position with respect to energy level (e.g., up corresponding to higher levels) although FIGS. 3B and 3C illustrate an example approximation. In some examples, a potential well can generally refer to a region surrounding a local minimum of potential energy. Further, potential well region 344A can also be referred to as a quantum well (e.g., a potential well having discrete energy values) as well as the quantum dot itself (e.g., semiconductor quantum dot 350A referring more generally to the overall structure including the quantum dot). In some implementations, potential well region 344A can be made of a different material (e.g., different semiconductor material and/or layers of different materials in heterostructures such as a Si/Ge heterostructure) as semiconductor channel 334. Further, in some implementations, a control signal, as can be applied via plunger gate 338A, can assist in forming potential well region 344A. However, an interface between different materials, such as an oxide layer 333A (e.g., made of an oxide and/or other dielectric or insulating material) can be inherently disordered and irregular such that electrons near such regions can exhibit decoherence or otherwise exhibit variable quantum electron valley state (e.g., qubit errors). Accordingly, keeping the electron within potential well region 344A and away from any oxide regions can improve coherence and stability of the quantum state, reducing error and/or noise.

As described above, barrier gate 336A and barrier gate 336B can keep the electron within potential well region 344A (e.g., along the x-axis in FIG. 3B) through the application of appropriate barrier gate signals. As further illustrated in FIG. 3B, a control signal 362 can be applied to plunger gate 338A along with a substrate voltage 364 applied to a bottom electrode 339A, which can correspond to a bulk electrode and in some implementations is formed from substrate 332 although in other examples can be formed from other materials/structures. In some examples, control signal 362 can correspond to a voltage for manipulating the electron in electron trap 340A. In some examples, substrate voltage 364 can correspond to an appropriate source and/or drain voltage, or any other voltage bias used with control signal 362. Moreover, in some examples, control signal 362 and substrate voltage 364 can keep the electron within potential well region 344A (e.g., along the y-axis in FIG. 3B). Accordingly, the electron can be kept within potential well region 344A along two dimensions (x and y) using barrier gate signals, control signal 362, and/or substrate voltage 364. In other words, the barrier gate signals, control signal 362, and substrate voltage 364 can control a 2D quantum dot.

However, semiconductor quantum dot 350A, and more specifically electron trap 340A is a three-dimensional structure such that potential well region 344A is a 3D region and the aforementioned signals do not provide control in the third dimension (e.g., along the z axis). FIG. 3C illustrates z-axis positioning control of the electron. As illustrated in FIG. 3C, an oxide region 341A and an oxide region 341B can be formed along sidewalls (e.g., a front and back side, respectively) of semiconductor channel 334, for instance to protect and separate semiconductor channel 334 from other structures, such as plunger gate 338A. As described above, the oxide interface region with these oxide layers are undesirable for the electron such that controlling the electron position in the z-axis can improve coherence.

In FIG. 3C, electrode 342A is disposed on the front side of electron trap 340A, and electrode 342B is disposed on the back side of electron trap 340A. A voltage signal 366 applied to electrode 342A and a voltage signal 368 applied to electrode 342B can accordingly keep the electron within potential well region 344A with respect to the z-axis. In other words, the voltage signals can be used to keep the electron isolated and away from undesirable regions/structures.

In some examples, a control system (e.g., control system 112) can include circuits (e.g., voltage controller circuits, classical logic gate circuits, etc.) for applying the voltage signals as described herein (e.g., control signal 362, substrate voltage 364, voltage signal 366, voltage signal 368, barrier gate signals, source/drain signals, etc.). Further, the voltage signals described herein can correspond to a direct current (DC) voltage signal, and/or a fluctuating voltage signal, such as an alternating current (AC) voltage signal, or other oscillating signal having for instance a frequency and/or waveform (e.g., radio frequency, microwave, etc.). In some examples, the control system can be programmed or otherwise interface with a program that to produce appropriate voltage signals, which in some implementations can be based on material properties, structure dimensions, temperature, etc. and further can be based on feedback, such as errors/noise in measurement, etc. In yet further examples, any of the voltage signals described herein in any combination can be used for manipulating the electron (e.g., including initializing, performing operations, measuring, etc.).

In some examples, the electron in electron trap 340B of semiconductor quantum dot 350B can be controlled by applying voltage signals to electrode 342C and/or electrode 342D similar to semiconductor quantum dot 350A as described above, in some instances being the same voltage signals as for semiconductor quantum dot 350A, and in other instances being specifically configured and/or tuned for semiconductor quantum dot 350B.

Although FIGS. 3A-3C illustrate an example architecture, in other examples, other shapes and/or structures and combinations thereof can be used. For example, one or more of the gate structures and/or electrodes can be implemented with other structures, such as metallic/conductive rings and/or other structures. Moreover, FIGS. 3A-3C illustrate simplified structures for explanation purposes and can omit certain structures, for instance layers between structures (e.g., one or more of the gate structures described can be offset from the semiconductor channel rather than directly disposed upon). FIG. 4A illustrates a semiconductor quantum dot 450C and FIG. 4B illustrates a semiconductor quantum dot 450D, each corresponding to alternative implementations of semiconductor quantum dot 350A and/or semiconductor quantum dot 350B. Semiconductor quantum dot 450C includes a plunger gate 438C, corresponding to plunger gate 338A, that includes or otherwise integrates a metallic ring structure. Semiconductor quantum dot 450D includes an isolated electrode 442E of various geometries, acting similarly, in addition or as replacement to electrode 342A, that in FIG. 4B includes or otherwise integrates a metallic ring structure. Although not illustrated in FIGS. 4A or 4B, additional metallic ring structures can be used for applying voltage signals, which can further have different shapes and/or sizes, as well as located in different positions, as in FIGS. 4C and 4D. FIG. 4C illustrates a semiconductor dot 450E and FIG. 4D illustrates a semiconductor do5 450F, each corresponding to an alternative implementations of semiconductor quantum dot 350A and/or semiconductor quantum dot 350B. FIG. 4C illustrates electrode 442E having different geometry as well as a different location near the electron trap and FIG. 4D illustrates electrode 442E having another location near the electron trap. Other examples not illustrated include other locations and arrangements, such as one or more electrodes located radially around (e.g., equidistant) the electron trap as well as integrated into structures and/or placed in separate structures.

FIG. 5 is a flow diagram of an exemplary method 500 for controlling positions of electrons in a semiconductor quantum dot. The steps shown in FIG. 5 can be performed by any suitable computer-executable code and/or computing system or other systems, including the system(s) illustrated in FIGS. 1, 2, 3A-3C and/or 4A-4B. In one example, each of the steps shown in FIG. 5 can be represented by multiple sub-steps, examples of which will be provided in greater detail below.

As illustrated in FIG. 5, at step 502 one or more of the systems described herein program a quantum dot implemented with a electron trap of a semiconductor channel having a plunger gate over the electron trap for applying a control signal. For example, control system 112 can program a quantum dot (e.g., semiconductor quantum dot 350A) of quantum processing device 110.

At step 504 one or more of the systems described herein apply a first voltage signal using a first electrode adjacent the plunger gate on a first side of the electron trap. For example, control system 112 can apply the first voltage signal using electrode 342A.

At step 506 one or more of the systems described herein apply a second voltage signal using a second electrode adjacent the plunger gate on a second side of the electron trap opposite the first side. For example, control system 112 can apply the second voltage using electrode 342B.

At step 508 one or more of the systems described herein control a position of an electron in the quantum dot using the control signal, the first voltage signal, and the second voltage signal. For example, control system 112 can control a position of the electron in electron trap 340A of semiconductor quantum dot 350A using the control signal (via plunger gate 338A), the first voltage signal (via electrode 342A), and the second voltage signal (via electrode 342B). Further, a bulk voltage signal (via bottom electrode 339A) can also be used.

The systems described herein can perform step 508 in a variety of ways. In one example, one or more of the voltage signals can be continuously applied, such as continuously applying a constant voltage and/or fluctuating voltage. In other examples, one or more of the voltage signals can be applied for a period of time and/or applied with a duty cycle. Further, in some examples, one or more of the voltage signals can be applied asynchronously and/or applied dynamically (e.g., in response to a manipulating the electron).

In some implementations, method 500 may further include programming a second quantum dot (e.g., semiconductor quantum dot 350B) implemented with a second electron trap (e.g., electron trap 340B) of the semiconductor channel (e.g., semiconductor channel 334) having a second plunger gate (e.g., plunger gate 338B) over the second electron trap for applying a second control signal. Method 500 can also include applying a third voltage signal using a third electrode (e.g., electrode 342C) adjacent the second plunger gate on a third side of the second electron trap, applying a fourth voltage signal using a fourth electrode (e.g., electrode 342D) adjacent the second plunger gate on a fourth side of the second electron trap opposite the third side, and controlling a position of a second electron in the second quantum dot using the second control signal (via plunger gate 338B), the third voltage signal (via electrode 342C), and the fourth voltage signal (via electrode 342D), as described herein.

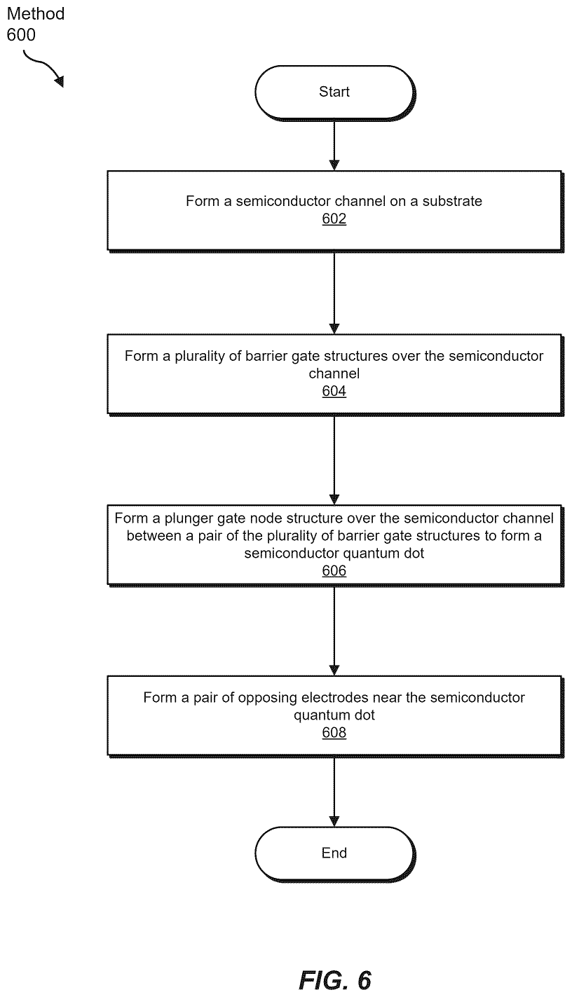

FIG. 6 is a flow diagram of an exemplary method 600 for fabricating a semiconductor quantum dot, such as portions of the system(s) illustrated in FIGS. 1, 2, 3A-3C and/or 4A-4B. The steps shown in FIG. 6 can be performed by any suitable fabrication system and/or methodology. In one example, each of the steps shown in FIG. 6 can be represented by multiple sub-steps, examples of which will be provided in greater detail below.

As illustrated in FIG. 6, at step 602 includes forming a semiconductor channel on a substrate. For example, semiconductor channel 334 can be formed on substrate 332 (e.g., via depositing/growing material onto substrate 332 and masking/etching to form semiconductor channel 334, depositing material onto substrate 332 and masking/etching away a channel and forming semiconductor channel 334 therein, etc.). In addition, the substrate and semiconductor channel can correspond to any appropriate material such as a glass insulator as a substrate and epitaxially grown silicon channel thereon.

Step 604 includes forming a plurality of barrier gate structures over the semiconductor channel. For example, multiple barrier gate structures (e.g., barrier gate 336A, barrier gate 336B, and/or barrier gate 336C) can be formed via various masking/etching and depositing steps.

Step 606 includes forming a plunger gate node structure over the semiconductor channel between a pair of the plurality of barrier gate structures to form a semiconductor quantum dot. For example, a plunger gate (e.g., plunger gate 338A) can be formed between a pair of barrier gates (e.g., barrier gate 336A and barrier gate 336B) via various masking/etching and depositing steps, which in some examples can coincide with step 604.

Step 608 includes forming a pair of opposing electrodes near the semiconductor quantum dot. For example, electrodes (e.g., electrode 342A and electrode 342B) can be formed from the plunger gate structure (e.g., via masking/etching and depositing oxide to form separate electrode structures). In other examples, the electrodes can be formed as needed based on desired locations and/or geometries.

In some examples, method 600 can include forming additional structures described herein such as forming a bottom electrode (e.g., bottom electrode 339A) as needed. Further, method 600 can include forming a second semiconductor quantum dot (e.g., semiconductor quantum dot 350B), for instance by forming a second plunger gate (e.g., plunger gate 338B) between a second pair of the plurality of barrier gate structures (e.g., barrier gate 336B and barrier gate 336C), and porting a second pair of opposing electrodes near the second semiconductor quantum dot.

Although method 600 describes various steps, in some examples, the steps can be combined and/or part of a common step, and can also be performed in other orders. For example, forming the various gate structures can include common masking and deposition steps. In addition, method 600 can include additional processing and/or finishing steps, such as addition of intervening layers as needed, removal of backing structures/materials, dicing of structures, doping steps, etc.

As detailed above, the present disclosure provides systems and methods to precisely control electron positioning inside crystalline structures such as Si and SiGe to reduce quantum bit errors. The systems and methods described herein include forming a quadrupole confinement region away from interface irregularities by adding additional (e.g., at least two) nodes to a quantum dot structure that can have nodes (e.g., four nodes corresponding to two barrier gates, a plunger gate, and a substrate) for silicon-on-insulator (SOI) architectures. The quadrupole ion trap descriptions provided herein can also be applied across various silicon or SiGe architectures such as planar, finfet, SOI, gate-all-around, etc.

Fluctuating voltages such as radio frequency (RF) can be used to maintain confinement. Further, DC levels can be variable depending on materials and dopings used. For example, ferro-electric materials can be used to establish DC level control.

Moreover, the systems and methods provided herein can advantageously be implemented with existing fabrication technologies. For example, the structures described herein can be fabricated using available manufacturing methods/facilities.

As detailed above, the computing devices and systems described and/or illustrated herein broadly represent any type or form of computing device or system capable of executing computer-readable instructions, such as those contained within the code/firmware/programs described herein. In their most basic configuration, these computing device(s) each include at least one memory device and at least one physical processor.

In some examples, the term “memory device” generally refers to any type or form of volatile or non-volatile storage device or medium capable of storing data and/or computer-readable instructions. In one example, a memory device stores, loads, and/or maintains one or more of the instructions and/or circuits described herein. Examples of memory devices include, without limitation, Random Access Memory (RAM), Read Only Memory (ROM), flash memory, Hard Disk Drives (HDDs), Solid-State Drives (SSDs), optical disk drives, caches, variations, or combinations of one or more of the same, or any other suitable storage memory.

In some examples, the term “physical processor” generally refers to any type or form of hardware-implemented processing unit capable of interpreting and/or executing computer-readable instructions. In one example, a physical processor accesses and/or modifies one or more instructions stored in the above-described memory device. Examples of physical processors include, without limitation, chiplets (e.g., smaller and in some examples more specialized processing units that can coordinate as a single chip), microprocessors, microcontrollers, Central Processing Units (CPUs), Field-Programmable Gate Arrays (FPGAs) that implement softcore processors, Application-Specific Integrated Circuits (ASICs), systems on chip (SoCs), digital signal processors (DSPs), Neural Network Engines (NNEs), accelerators, accelerated processing units (APUs), portions of one or more of the same, variations or combinations of one or more of the same (e.g., a host processor and a co-processor), and/or any other suitable physical processor.

In some examples, the term “physical processor” also refers to and/or includes a co-processor that generally refers to any type or form of hardware-implemented processing unit capable of interpreting and/or executing computer-readable instructions, which in some examples works in conjunction with and/or based on instructions from a host/main processor such as a CPU, and further in some examples accesses and/or modifies one or more instructions stored in the above-described memory device. Examples of co-processors include, without limitation, chiplets, microprocessors, microcontrollers, graphics processing units (GPUs), FPGAS that implement softcore processors, ASICs, SoCs, DSPs, NNEs, accelerators, portions of one or more of the same, variations or combinations of one or more of the same, and/or any other suitable physical processor.

In some examples, the term “quantum processor,” “quantum processing unit (QPU),” “quantum processing device,” “quantum computer” and/or “quantum computing device” generally refers to any hardware and/or logic capable of and/or contributes to quantum computing, in which information (e.g., analogous to bits) are encoded in quantum bits (“qubits”) and more specifically each bit encoded as a state of a single particle, such as electrons or photons, which further allow superpositions of states not possible with classical bits. Examples of quantum processor architectures include solid state quantum computers, superconducting quantum computers, trapped-ion quantum computers, spin qubit quantum computers, photonics, linear optical quantum computing, photonic quantum computing, neutral atoms in optical lattices, nuclear magnetic resonance quantum computing, etc.

Although described as separate elements/steps, the instructions described and/or illustrated herein can represent portions of a single program or application, including instructions implemented in code, firmware, one or more circuits, etc. In addition, in certain implementations one or more of these instructions can represent one or more software applications or programs that, when executed by a computing device, cause the computing device to perform one or more tasks. For example, one or more of the instructions described and/or illustrated herein represent instructions stored and configured to run on one or more of the computing devices or systems described and/or illustrated herein. In some implementations, one or more instructions can be implemented as a circuit or circuitry, including as part of a firmware, a ROM, one or more logic units, etc. One or more of these instructions can also represent or otherwise be implemented with all or portions of one or more special-purpose computers configured to perform one or more tasks.

In some implementations, the term “computer-readable medium” generally refers to any form of device, carrier, or medium capable of storing or carrying computer-readable instructions. Examples of computer-readable media include, without limitation, transmission-type media, such as carrier waves, and non-transitory-type media, such as magnetic-storage media (e.g., hard disk drives, tape drives, and floppy disks), optical-storage media (e.g., Compact Disks (CDs), Digital Video Disks (DVDs), and BLU-RAY disks), electronic-storage media (e.g., solid-state drives and flash media), and other distribution systems.

The process parameters and sequence of the steps described and/or illustrated herein are given by way of example only and can be varied as desired. For example, while the steps illustrated and/or described herein are shown or discussed in a particular order, these steps do not necessarily need to be performed in the order illustrated or discussed. The various exemplary methods described and/or illustrated herein can also omit one or more of the steps described or illustrated herein or include additional steps in addition to those disclosed.

The preceding description has been provided to enable others skilled in the art to best utilize various aspects of the exemplary implementations disclosed herein. This exemplary description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A device comprising:
a semiconductor channel;
a first barrier gate surrounding the semiconductor channel;
a second barrier gate surrounding the semiconductor channel;
an electron trap of the semiconductor channel defined between the first and second barrier gates to trap an electron corresponding to a qubit;
a plunger gate over the electron trap and configured for a control signal for the qubit;
a first electrode near the electron trap and configured for a first voltage signal;
a second electrode near the electron trap and configured for a second voltage signal; and
a bottom electrode opposite the plunger gate.

2. The device of claim 1, wherein the electron trap comprises an oxide interface region and the first and second electrodes are configured to position the electron away from the oxide interface region.

3. The device of claim 2, wherein the bottom electrode is bulk silicon and is configured to position the electron away from the oxide interface region.

4. The device of claim 2, wherein the plunger gate is further configured to position the electron away from the oxide interface region.

5. The device of claim 1, wherein at least one of the first and second voltage signals corresponds to a direct current (DC) signal or a fluctuating voltage signal.

6. The device of claim 1, further comprising a second electron trap of the semiconductor channel to trap a second electron corresponding to a second qubit.

7. The device of claim 6, wherein the second qubit is configured for entanglement with the first qubit.

8. The device of claim 6, further comprising a third barrier gate surrounding the semiconductor channel, wherein the second electron trap is defined between the second and third barrier gates.

9. The device of claim 6, further comprising:
a second plunger gate over the second electron trap and configured for a second control signal for the second qubit; and
a second bottom electrode oppose the second plunger gate.

10. The device of claim 9, further comprising:
a third electrode near the second electron trap and configured for a third voltage signal; and
a fourth electrode near the second electron trap opposite the third electrode and configured for a fourth voltage signal.

11. The device of claim 10, wherein the second electron trap comprises a second oxide interface region and the third and fourth electrodes are configured to position the second electron away from the second oxide interface region.

12. The device of claim 10, wherein at least one of the third and fourth voltage signals corresponds to a direct current (DC) signal or a fluctuating voltage signal.

13. A system comprising:
a control system; and
a quantum processing device comprising:
a semiconductor channel;
a first barrier gate surrounding the semiconductor channel;
a second barrier gate surrounding the semiconductor channel;
an electron trap of the semiconductor channel defined between the first and second barrier gates to trap an electron corresponding to a qubit, the electron trap comprising an oxide interface region;
a plunger gate over the electron trap and configured for a control signal for the qubit;
a first electrode adjacent the plunger gate on a first side of the electron trap and configured for a first voltage signal;
a second electrode adjacent the plunger gate on a second side of the electron trap opposite the first side and configured for a second voltage signal; and
a bottom electrode opposite the plunger gate,
wherein the control system is configured to coordinate the control signal, the first voltage signal, and the second voltage signal to position the electron away from the oxide interface region.

14. The system of claim 13, wherein at least one of the first and second voltage signals corresponds to a direct current (DC) signal or a fluctuating voltage signal.

15. The system of claim 13, wherein the quantum processing device further comprises:
a third barrier gate surrounding the semiconductor channel;
a second electron trap of the semiconductor channel defined between the second and third barrier gates to trap a second electron corresponding to a second qubit; and
a second plunger gate over the second electron trap and configured for a second control signal for the second qubit.

16. The system of claim 15, wherein the second qubit is configured for entanglement with the first qubit.

17. The system of claim 15, further comprising:
a third electrode adjacent the second plunger gate on a first side of the second electron trap and configured for a third voltage signal; and
a fourth electrode adjacent the second plunger gate on a second side of the second electron trap opposite the first side and configured for a fourth voltage signal,
wherein the second electron trap comprises a second oxide interface region and the control system is configured to coordinate the second control signal, the third voltage signal, and the fourth voltage signal to position the second electron away from the second oxide interface region.

18. The system of claim 17, wherein at least one of the third and fourth voltage signals corresponds to a direct current (DC) signal or a fluctuating voltage signal.

19. A method comprising:
forming a semiconductor channel on a substrate;
forming a plurality of barrier gate structures over the semiconductor channel;
forming a plunger gate node structure over the semiconductor channel between a pair of the plurality of barrier gate structures to form a semiconductor quantum dot; and
forming a pair of opposing electrodes near the semiconductor quantum dot.

20. The method of claim 19, further comprising:
forming a second plunger gate node structure over the semiconductor channel between a second pair of the plurality of barrier gate structures to form a second semiconductor quantum dot; and
forming a second pair of opposing electrodes near the second semiconductor quantum dot.
